(19) United States
(12) Patent Application Publication
(10) Pub. No.: US 2024/0171908 A1
(43) Pub. Date: May 23, 2024

(54) ELECTRONIC DEVICE WITH SPEAKER PROTECTION MECHANISM

(71) Applicant: ACER INCORPORATED, New Taipei City (TW)

(72) Inventors: Po-Jen Tu, New Taipei City (TW); Jia-Ren Chang, New Taipei City (TW); Kai-Meng Tzeng, New Taipei City (TW)

(73) Assignee: ACER INCORPORATED, New Taipei City (TW)

(21) Appl. No.: 18/117,486

(22) Filed: Mar. 6, 2023

(30) Foreign Application Priority Data
Nov. 22, 2022 (TW) 111144498

(51) Int. Cl. H04R 3/00; H03F 3/185; H03G 3/30

(52) U.S. Cl. CPC H04R 3/007; H03F 3/185; H03G 3/3026; H03F 2200/03

(57) ABSTRACT

An electronic device includes a speaker, an amplifier circuit, a level shift circuit, a switch and a processor. The speaker is configured to operate according to a driving signal. The amplifier is configured to receive an input signal provided by the processor and provide an output signal by adjusting the input signal. The level shift circuit is configured to provide an adjusted output signal by adjusting the output signal. The switch is configured to selectively transmit the output signal to the speaker for providing the driving signal according to an activation signal. The processor is configured to detect real-time characteristics of the adjusted output signal and provide the activation signal based on the real-time characteristics of the adjusted output signal.

### BACKGROUND OF THE INVENTION

### 1. Field of the Invention

The present invention is related to an electronic device, and more particularly, to an electronic device with speaker protection mechanism.

### 2. Description of the Prior Art

A speaker is an electronic device capable of converting electrical signals into audio signals and normally includes diaphragms and a control circuit made of electromagnets and coils. When the current of the speaker control signal corresponding to a specific frequency flows through the coils in the speaker, the coils vibrate in the same frequency of the current. The diaphragms attached to the coils also start to vibrate, thereby causing disturbance in surrounding air for producing sound.

In a prior-art electronic device, a speaker may operate according to a driving signal. The input signal associated with the audio signal to be played by the speaker may be provided by a processor and amplified by an amplifier circuit for providing the driving signal. In order to ensure proper physical quantities of the speaker during operation (such as temperature, voltage, current or excursion), the prior-art electronic device normally adopts a protection circuit disposed at the front-end of the amplifier circuit for cutting off the input signal when detecting an anomaly in the input signal, thereby preventing the amplified abnormal driving signal from damaging the speaker. However, the prior art electronic device is unable to provide speaker protection mechanism if the setting of the speaker is erroneous, wherein a normal input signal is amplified into an abnormal output signal hazardous to the speaker.

Therefore, there is a need for an electronic device with speaker protection mechanism which minimizes the chance of damaging the speaker.

### SUMMARY OF THE INVENTION

The present invention provides an electronic device with speaker protection mechanism and including a speaker, an amplifier circuit, a level shift circuit, a switch and a processor. The speaker is configured to operate according to a driving signal. The amplifier circuit is configured to receive an input signal and provide an output signal by adjusting the input signal. The level shift circuit is configured to provide an adjusted output signal by adjusting the output signal. The switch is coupled between the amplifier circuit and the speaker and configured to selectively transmit the output signal to the speaker according to an activation signal for providing the driving signal. The processor is configured to provide the input signal, detect a real-time characteristic of the adjusted output signal, and provide the activation signal based on the real-time characteristic of the adjusted output signal.

The present invention also provides a method of providing speaker protection mechanism in an electronic device. The method includes operating a speaker in the electronic device according to a driving signal, providing an input signal associated with an audio signal to be displayed by the speaker using a processor in the electronic device, providing an output signal by adjusting the input signal using an amplifier circuit in the electronic device, providing an adjusted output signal by adjusting the output signal using a level shift circuit in the electronic device, selectively transmitting the output signal to the speaker according to an activation signal for providing the driving signal using a switch in the electronic device which is coupled between the amplifier circuit and the speaker, detecting a real-time characteristic of the adjusted output signal using the processor, and providing the activation signal based on the real-time characteristic of the adjusted output signal using the processor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional diagram illustrating an electronic device with speaker protection mechanism according to an embodiment of the present invention.

FIG. 2 is a functional diagram illustrating an electronic device with speaker protection mechanism according to another embodiment of the present invention.

FIG. 3 is a diagram illustrating the implementation of a level shift circuit in an electronic device according to an embodiment of the present invention.

### DETAILED DESCRIPTION

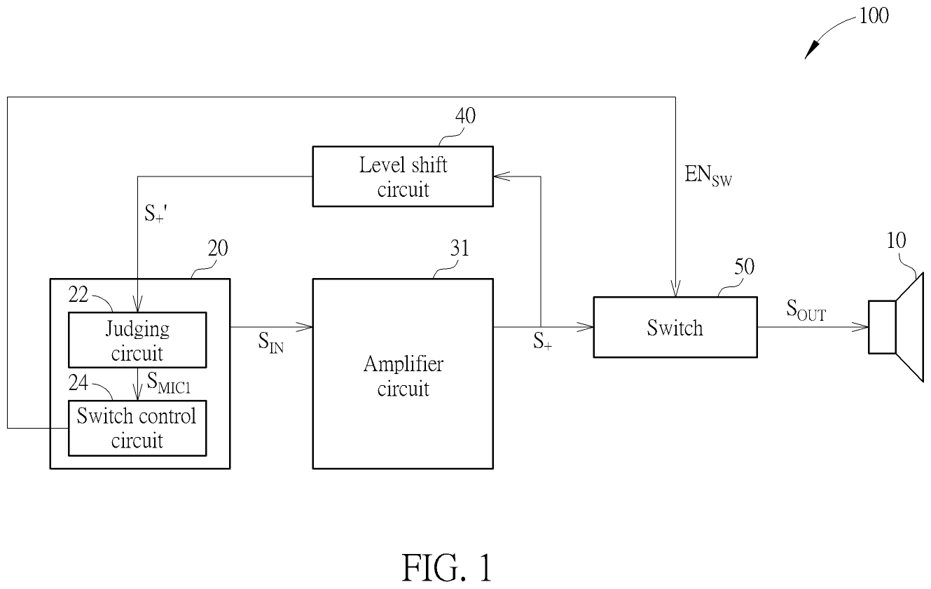

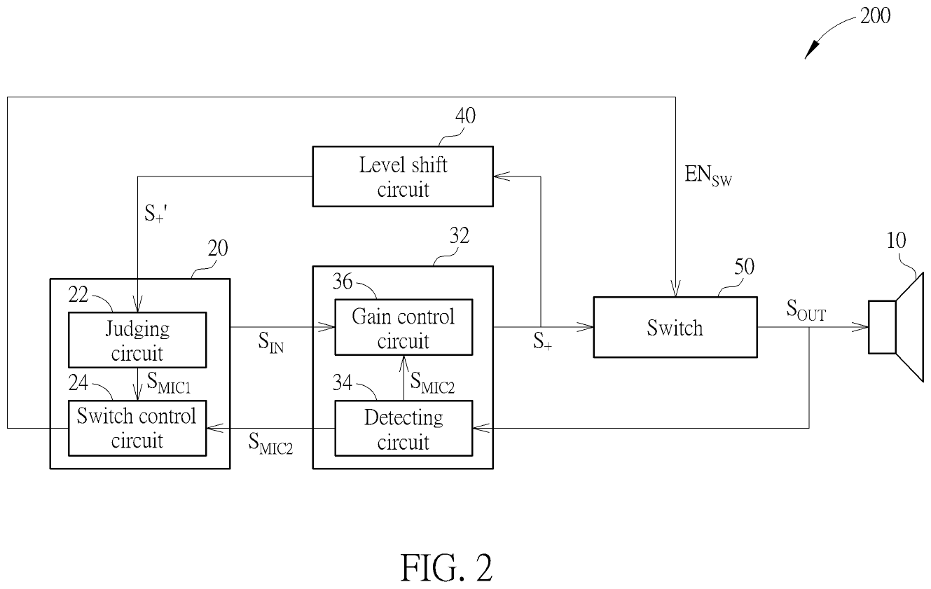

FIG. 1 is a functional diagram illustrating an electronic device 100 with speaker protection mechanism according to an embodiment of the present invention. FIG. 2 is a functional diagram illustrating an electronic device 200 with speaker protection mechanism according to another embodiment of the present invention. The electronic device 100 includes a speaker 10, a processor 20, an amplifier circuit 31, a level shift circuit 40, and a switch 50. The electronic device 200 includes a speaker 10, a processor 20, an amplifier circuit 32, a level shift circuit 40, and a switch 50.

In the electronic devices 100 and 200 of the present invention, the speaker 10 may be a dynamic speaker, an electromagnet speaker, a piezoelectric speaker, an electrostatic speaker or a plasma speaker. In an embodiment, each speaker may be a woofer, a subwoofer, a mid-range speaker, a tweeter, a super tweeter, a coaxial speaker or a full-range speaker. However, the type of the speaker 10 does not limit the scope of the present invention.

In the electronic devices 100 and 200 of the present invention, the processor 20 may be a platform controller hub (PCH) or a digital signal processor (DSP) configured to provide an input signal S_{IN} associated with the audio signal to be played by the speaker 10. The amplifier circuits 31 and 32 are configured to convert the input signal S_{IN} into an output signal S+ and selectively transmit the output signal S+ to the speaker 10 via the switch 50 for providing a driving signal S_{OUT} More specifically, the amplifier circuits 31 and 32 are configured to adjust the input signal S_{IN} with a specific gain (amplify the input signal S_{IN}) for providing the corresponding driving signal S_{OUT}.

In the electronic device 100 depicted in FIG. 1, the amplifier circuit 31 is configured to amplify the input signal S_{IN} using a predetermined constant gain for providing the output signal S+.

In the electronic device 200 depicted in FIG. 2, the amplifier circuit 32 is a smart amplifier which includes a detecting circuit 34 and a gain control circuit 36. The input end of the detecting circuit 34 is coupled between the speaker 10 and the switch 50 for receiving the driving signal S_{OUT}. The detecting circuit 34 is configured to detect the real-time characteristics of the driving signal S_{OUT} and output a corresponding characteristic signal S_{MIC2} at its output end. In an embodiment, the characteristic signal S_{MIC2} includes the voltage value, the current value, the power, the frequency response and/or the gradient variation associated with the driving signal S_{OUT}.

The gain control circuit 36 is coupled to the processor 20 for receiving the input signal S_{IN} and coupled to the detecting circuit 32 for receiving the characteristic signal S_{MIC2}. The gain control circuit 36 is configured to adjust the gain for amplifying the input signal S_{IN} according to the characteristic signal S_{MIC2}. When the value of the characteristic signal S_{MIC2} is not within a predetermined range, it indicates that an anomaly has occurs in the current driving signal S_{OUT}, and the speaker 10 may be damaged due to over-excursion and/or coil over-heat when operating based on the current abnormal driving signal S_{OUT}. Under such circumstance, the gain control circuit 36 is configured to suppress the output signal S+ (i.e., reduce the gain for amplifying the input signal S_{IN}) in order to avoid possible damages to the speaker 10.

In the electronic devices 100 and 200 of the present invention, the switch 50 is configured to selectively transmit the output signal S+ to the speaker 10 according to an activation signal EN_{SW} for providing the driving signal S_{OUT}. In an embodiment of the present invention, the switch 50 may include a metal-oxide-semiconductor field-effect transistor (MOSFET), a bipolar junction transistor (BJT) or any device providing similar function. However, the type of the switch 50 does not limit the scope of the present invention.

In the electronic devices 100 and 200 of the present invention, the level shift circuit 40 includes an input end coupled to the output end of the amplifier circuit 30 for receiving the output signal S+, and an output end coupled to the processor 20 for outputting an adjusted output signal S+′. The level shift circuit 40 is configured to provide the adjusted output signal S+′ by adjusting the output signal S+. In an embodiment, the level shift circuit 40 may convert the output signal S+ having the level of the speaker 10 (such as 1V) to the adjusted output signal S+′ having the level of an analog microphone (such as 0.5V) which can be processed by the processor 20. In an embodiment, the level shift circuit 40 may block the direct-current (DC) component in the output signal S+ for providing the adjusted output signal which only includes the alternative-current (AC) component.

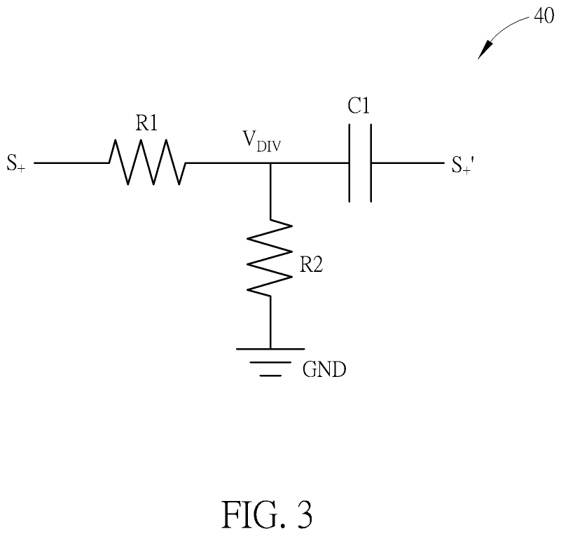

FIG. 3 is a diagram illustrating the implementation of the level shift circuit 40 in the electronic devices 100 and 200 according to an embodiment of the present invention. The level shift circuit 40 may include resistors R1-R2 and a capacitor C1. The resistors R1 and R2 are coupled in series between the input end of the level shift circuit 40 and a ground level GND. The resistors R1 and R2 form a voltage-diving circuit capable of providing a voltage-diving signal Spiv associated with the output signal S+, wherein S_{DIV}=R2*S+/(R1+R2). The first end of the capacitor C1 is coupled between the resistors R1 and R2 for receiving the voltage-diving signal S_{DIV}. The second end of the capacitor C1 is coupled to the output end of the level shift circuit 40 for blocking the DC component in the output signal S+ so that the adjusted output signal only includes the AC component. However, the implementation of the level shift circuit 40 depicted in FIG. 3 in only an embodiment and does not limit the scope of the present invention.

In the electronic devices 100 and 200 of the present invention, the processor 20 may include a judging circuit 22 and a switch control circuit 24. The judging circuit 22 is configured to detect the real-time characteristic of the adjusted output signal S+′ and output a corresponding characteristic signal S_{MIC1} at its output end. In an embodiment, the characteristic signal S_{MIC1} includes the voltage value, the current value, the power, the frequency response and/or the gradient variation associated with the adjusted output signal S+′.

In the electronic device 100 of the present invention, the switch control circuit 24 is configured to output the activation signal EN_{SW} having different levels according to the characteristic signal S_{MIC1}. When the value of the characteristic signal S_{MIC1} is within a predetermined range, it indicates that the output signal S+ is normal, and the switch control circuit 24 is configured to output the activation signal EN_{SW} having an enable level (such as high level) for turning on the switch 50, thereby transmitting the output signal S+ for providing the corresponding driving signal S_{OUT}. When the value of the first characteristic signal S_{MIC1} is not within the predetermined range, it indicates that anomaly has occurred in the output signal S+ (and subsequently also in the driving signal S_{OUT}), possibly caused by abnormal input signal S_{IN} at the front-end of the speaker 10 or erroneous setting of the speaker 10 which results in abnormal output signal S+ at the back-end of the speaker 10. Under such circumstance, the speaker 10 may be damaged due to over-excursion and/or coil over-heat when continuing to operate based on the abnormal driving signal S_{OUT}. In response, the switch control circuit 24 is configured to output the activation signal EN_{SW} having a disable level (such as low level) for turning off the switch 50, thereby cutting off the transmission of the output signal S+ so as to stop supplying the driving signal S_{OUT}.

In the electronic device 200 of the present invention, the switch control circuit 24 is configured to output the activation signal EN_{SW} having different levels according to the characteristic signals S_{MIC1} and S_{MIC2}. When the value of the characteristic signal S_{MIC1} and the value of the characteristic signal S_{MIC2} are both within respective predetermined ranges, it indicates that the output signal S+ and the driving signal S_{OUT} are normal, and the switch control circuit 24 is configured to output the activation signal EN_{SW} having an enable level (such as high level) for turning on the switch 50, thereby transmitting the output signal S+ for providing the corresponding driving signal S_{OUT}. When the value of either the characteristic signal S_{MIC1} or the characteristic signal S_{MIC2} is not within its predetermined range, it indicates that an anomaly has occurred in the output signal S+ or the driving signal S_{OUT}, possibly caused by abnormal input signal S_{IN} at the front-end of the speaker 10 or erroneous setting of the speaker 10 which results in abnormal output signal S+ at the back-end of the speaker. Under such circumstance, the speaker 10 may be damaged due to over-excursion and/or coil over-heat when continuing to operate based on the abnormal driving signal S_{OUT}. In response, the switch control circuit 24 is configured to output the activation signal EN_{SW} having a disable level (such as low level) for turning off the switch 50, thereby cutting off the transmission of the output signal S+ so as to stop supplying the driving signal S_{OUT}.

In conclusion, in the electronic device of the present invention, a protection circuit (i.e., the switch 50) is disposed at the back-end of the amplifier circuits 31 and 32 for cutting off the transmission of the output signal S+ when detecting an anomaly in the output signal S+ or the driving signal S_{OUT}, so as to stop supplying the abnormal driving signal S_{OUT} and prevent possible damages to the speaker 10. The present electronic device can provide complete speaker protection mechanism against the abnormal input signal S_{IN} at the front-end of the speaker 10 or the abnormal output signal S+ at the back-end of the speaker 10 caused by erroneous setting of the speaker 10.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device with speaker protection mechanism, comprising:
a speaker configured to operate according to a driving signal;
an amplifier circuit configured to receive an input signal and provide an output signal by adjusting the input signal;
a level shift circuit configured to provide an adjusted output signal by adjusting the output signal;
a switch coupled between the amplifier circuit and the speaker and configured to selectively transmit the output signal to the speaker according to an activation signal for providing the driving signal; and
a processor configured to:
provide the input signal;
detect a real-time characteristic of the adjusted output signal; and
provide the activation signal based on the real-time characteristic of the adjusted output signal.

2. The electronic device of claim 1, wherein the processor comprises:
a judging circuit coupled to the level shift circuit for receiving the adjusted output signal, and configured to detect the real-time characteristic of the adjusted output signal and output a first characteristic signal based on the real-time characteristic of the adjusted output signal; and
a switch control circuit coupled to the judging circuit for receiving the first characteristic signal and configured to:
output the activation signal having an enable level for turning on the switch when a value of the first characteristic signal is within a first predetermined range; and
output the activation signal having a disable level for turning off the switch when the value of the first characteristic signal is not within the first predetermined range.

3. The electronic device of claim 2, wherein the first characteristic signal includes a voltage value, a current value, a power, a frequency response and/or a gradient variation associated with the adjusted output signal.

4. The electronic device of claim 1, wherein the amplifier circuit comprises:
a detecting circuit coupled between the speaker and the switch for receiving the driving signal, and configured to detect a real-time characteristic of the driving signal and output a second characteristic signal based on the real-time characteristic of the driving signal; and
a gain control circuit coupled to the processor for receiving the input signal and coupled to the detecting circuit for receiving the second characteristic signal, and configured to adjust a gain for amplifying the input signal according to the second characteristic signal.

5. The electronic device of claim 4, wherein the second characteristic signal includes a voltage value, a current value, a power, a frequency response and/or a gradient variation associated with the driving signal.

6. The electronic device of claim 4, wherein the processor comprises:
a judging circuit coupled to the level shift circuit for receiving the adjusted output signal, and configured to detect the real-time characteristic of the adjusted output signal and output a first characteristic signal based on the real-time characteristic of the adjusted output signal; and
a switch control circuit coupled to the judging circuit for receiving the first characteristic signal and coupled to the detecting circuit for receiving the second characteristic signal, and configured to:
output the activation signal having an enable level for turning on the switch when a value of the first characteristic signal is within a first predetermined range and a value of the second characteristic signal is within a second predetermined range; and
output the activation signal having a disable level for turning off the switch when the value of the first characteristic signal is not within the first predetermined range or the value of the second characteristic signal is not within the second predetermined range.

7. The electronic device of claim 1, wherein the level shift circuit is further configured to adjust a level of the output signal for providing the adjusted output signal.

8. The electronic device of claim 7, wherein the level shift circuit is further configured to block a direct-current (DC) component in the output signal for providing the adjusted output signal which only includes an alternative-current (AC) component.

9. The electronic device of claim 1, wherein the level shift circuit comprises:
a first resistor including:
a first end coupled between the amplifier circuit and the switch for receiving the output signal; and
a second end;
a second resistor including:
a first end coupled to the second end of the first resistor; and
a second end coupled to a ground level; and
a capacitor including:
a first end coupled to the second end of the first resistor and the first end of the second resistor; and
a second end coupled to the processor for outputting the adjusted output signal.

10. The electronic device of claim 1, wherein the processor is platform controller hub (PCH) or a digital signal processor (DSP).

11. A method of providing speaker protection mechanism in an electronic device, comprising:
operating a speaker in the electronic device according to a driving signal;
providing an input signal associated with an audio signal to be displayed by the speaker using a processor in the electronic device;
providing an output signal by adjusting the input signal using an amplifier circuit in the electronic device;
providing an adjusted output signal by adjusting the output signal using a level shift circuit in the electronic device;
selectively transmitting the output signal to the speaker according to an activation signal for providing the driving signal using a switch in the electronic device which is coupled between the amplifier circuit and the speaker;
detecting a real-time characteristic of the adjusted output signal using the processor; and
providing the activation signal based on the real-time characteristic of the adjusted output signal using the processor.

12. The method of claim 11, further comprising:
outputting a first characteristic signal based on the real-time characteristic of the adjusted output signal using a judging circuit in the processor;
outputting the activation signal having an enable level for turning on the switch when a value of the first characteristic signal is within a first predetermined range using a switch control circuit in the processor; and
outputting the activation signal having a disable level for turning off the switch when the value of the first characteristic signal is not within the first predetermined range.

13. The method of claim 12, wherein the first characteristic signal includes a voltage value, a current value, a power, a frequency response and/or a gradient variation associated with the adjusted output signal.

14. The method of claim 11, further comprising:
outputting a second characteristic signal based on the real-time characteristic of the driving signal using a judging circuit in the amplifier circuit;
adjust a gain for amplifying the input signal according to the second characteristic signal using a gain control circuit in the amplifier circuit.

15. The method of claim 14, wherein the second characteristic signal includes a voltage value, a current value, a power, a frequency response and/or a gradient variation associated with the driving signal.

16. The method of claim 14, further comprising:
outputting a first characteristic signal based on the real-time characteristic of the adjusted output signal using a judging circuit in the processor;
outputting the activation signal having an enable level using a switch control circuit in the processor for turning on the switch when a value of the first characteristic signal is within a first predetermined range and a value of the second characteristic signal is within a second predetermined range; and
outputting the activation signal having a disable level using the switch control circuit for turning off the switch when the value of the first characteristic signal is not within the first predetermined range or the value of the second characteristic signal is not within the second predetermined range.

17. The method of claim 11, further comprising:
adjusting a level of the output signal for providing the adjusted output signal using the level shift circuit.

18. The method of claim 17, further comprising:
blocking a direct-current (DC) component in the output signal using the level shift circuit for providing the adjusted output signal which only includes an alternative-current (AC) component.
